(19) United States
(12) Patent Application Publication
(10) Pub. No.: US 2005/0073301 A1
(43) Pub. Date: Apr. 7, 2005

(54) Sensor element and gradiometer assemblage, use thereof for measuring magnetic field gradients, and method therefor

(76) Inventors: Ingo Herrmann, Leinfelden-Echterdingen (DE); Henrik Siegle, Leonberg (DE)

Correspondence Address: KENYON & KENYON, ONE BROADWAY, NEW YORK, NY, 10004, US

(21) Appl. No.: 10/400,863

(22) Filed: Mar. 26, 2003

(30) Foreign Application Priority Data
Mar. 28, 2002 (DE) 102 13 941.5-33

(51) Int. Cl. G01R 33/02

(52) U.S. Cl. 324/244

(57) ABSTRACT

A sensor element is described having a substrate and a first magnetoresistive layered assemblage having at least locally a first strip having a first strip width, and a second magnetoresistive layered assemblage having at least locally a second strip having a second strip width different from the first strip width. A gradiometer assemblage is described having at least two gradiometer bridges which have magnetoresistive, at least locally strip-shaped, layered assemblages of this kind, the strips in the individual gradiometer bridges being of different widths. This sensor element or gradiometer assemblage is suitable in particular for measuring magnetic field gradients over at least five orders of magnitude at magnetic field strengths from 1 μT to 30 mT, in particular from 1 μT to 10 mT. A method for measuring magnetic field gradients using a sensor element or a gradiometer assemblage of this kind is described, an overall measurement range exceeding the measurement range of an individual layered assemblage being obtained by way of a different setting of the width of the strips.

### FIELD OF THE INVENTION

The present invention relates to a sensor element and a gradiometer assemblage for measuring magnetic field gradients, as well as a method for measuring magnetic field gradients using a sensor element or a gradiometer assemblage.

### BACKGROUND INFORMATION

Magnetic sensors are widely used in motor vehicles, for example as rotation speed sensors on the wheel, as rotation speed or travel transducers for the motor control system, or as steering angle sensors for vehicle dynamics control systems. Magnetic sensors are also used in current sensor technology, for example for electrical battery management of motor vehicles. The problem occurring in this context is that the currents which occur are very different, so that the sensors must detect magnetic field gradients over at least five orders of magnitude; and that no technology has hitherto been available that can cover this measurement range with one sensor element. A cost-intensive assemblage of multiple sensors covering different measurement ranges has therefore hitherto been necessary.

Magnetoresistive sensor elements based on giant magnetoresistive (GMR) technology and anisotropic magnetoresistance (AMR) technology, which operate on the principle either of coupled multiple-ply layered systems or spin-valve layered systems, and gradiometer assemblages constructed therewith, are fundamentally known from the existing art. Reference may be made in that context, for example, to German Patent Application No. 101 28 135.8, in which magnetoresistive layered assemblages and gradiometers having such layered assemblages based on GMR or AMR technology are explained in detail. An overview of magnetoresistive sensor elements is also described by U. Dibbern in “Sensors—A Comprehensive Survey.” edited by W. Göpel et al., Vol. 5, Magnetic Sensors, VCH-Verlag, Weinheim, 1989, pp. 342-380.

### SUMMARY

An object of the present invention is to make available a sensor element and a gradiometer assemblage with which magnetic field gradients can be detected over the widest possible measurement range using a single sensor element. An object is to measure magnetic field gradients, using a sensor element or gradiometer assemblage of this kind, over at least five orders of magnitude at typical magnetic field strengths of between 1/T and 30 mT, in particular from 1/T to 10 mT.

An example sensor element and example gradiometer assemblage according to the present invention have, as compared to the existing devices, the advantage that magnetic field gradients can be detected therewith over a very wide measurement range. It is additionally advantageous that with a plurality of magnetoresistive layered assemblages, each being patterned at least locally, in particular (if possible) completely, in strip-shaped fashion, a differing width of the strips of these magnetoresistive layered assemblages can be established in controlled fashion in such a way that in terms of the measurement range of the overall sensor element obtained, or the overall gradiometer assemblage obtained, a total measurement range of the multiple layered assemblages is obtained, for the magnetic field gradients to be measured, that exceeds the individual measurement range of one individual layered assemblage.

In addition, it may be advantageous (compared to the existing art) that the example sensor element and the example gradiometer assemblage according to the present invention can be of very compact configuration and can be integrated onto a common sensor chip while requiring a very small installation space. This results, in particular, in a very low outlay for packaging of the sensor element or the gradiometer assemblage, and in greatly reduced production and assembly costs.

Lastly, it may be advantageous in the context of the example sensor element and the example gradiometer assemblage according to the present invention that, especially in the case of magnetoresistive layered systems based on the GMR effect and operating on the spin-valve principle, the slope of the characteristic curve of the magnetoresistive layered assemblage, i.e., the change in electrical resistance in the intermediate layer as a function of the change in an externally applied magnetic field, and thus also the working range or individual measurement range and the sensitivity of the magnetoresistive layered assemblage, can be adjusted very easily by way of the strip width (in plan view) with which the layered assemblage is patterned or configured.

It is sufficient in principle if the layered assemblage is embodied at least locally in strip form, in plan view; preferably, however, it is embodied at least largely or entirely in strip form, this also being understood as meanders that are embodied at least in part in strip form.

It is thus now possible to apply, on a common substrate or a common sensor chip, several interconnected magnetoresistive layered assemblages that have different feature widths or strip widths and thus different sensitivities and working ranges, thus yielding an enlarged overall measurement range.

It may be particularly advantageous if the strips have a width in the range from 0.5 μm to 200 μm, in particular from 1 μm to 100 μm.

It moreover may be particularly advantageous if the sensor element has two or three magnetoresistive layered assemblages, a first magnetoresistive layered assemblage being patterned in strip form with a first strip width that lies in the range between 0.5 μm and 2 μm; if a second magnetoresistive layered assemblage is patterned in strip form with a second strip width that lies in the range between 8 μm and 15 μm; and if a third magnetoresistive layered assemblage is patterned in strip form with a third strip width that lies in the range between 3 μm and 7 μm. Magnetic field gradients can be measured particularly well in this fashion over at least five orders of magnitude, at typical fields of about 5 mTesla.

It may be furthermore advantageous if, in the case of the sensor element according to the present invention and in the case of the gradiometer assemblage according to the present invention, there is also simultaneously provided, on the substrate having the magnetoresistive layered assemblages, an electrical evaluation unit interconnected thereto. The latter can, however, also be positioned outside the common substrate, although this requires the provision of signal outputs and interfaces, and a larger configuration.

Lastly, a particularly simple and advantageous gradiometer assemblage is obtained if two or three full gradiometer bridges are provided on the common substrate, each of these full gradiometer bridges having, in particular, four magnetoresistive layered assemblages interconnected in the manner of a Wheatstone bridge, the strip widths within these magnetoresistive layered assemblages interconnected into a Wheatstone bridge preferably being identical, and the strip widths being different in each case between the magnetoresistive layered assemblages associated with the various Wheatstone bridge circuits.

### BRIEF DESCRIPTION OF THE DRAWINGS

The present invention will be explained in more detail with reference to the drawings and the description below.

FIG. 1 is a perspective depiction of a magnetoresistive layered assemblage on a substrate.

FIG. 2 is a schematic sketch of a Wheatstone bridge circuit having four magnetoresistive layered assemblages according to FIG. 1.

FIG. 3 is a schematic sketch of a gradiometer having a full gradiometer bridge.

FIG. 4 depicts a detail of FIG. 3 with meander-shaped magnetoresistive layered assemblages.

FIG. 5 shows an assemblage of several full gradiometer bridges or gradiometers according to FIG. 4 on a common substrate, yielding a gradiometer assemblage.

### DETAILED DESCRIPTION

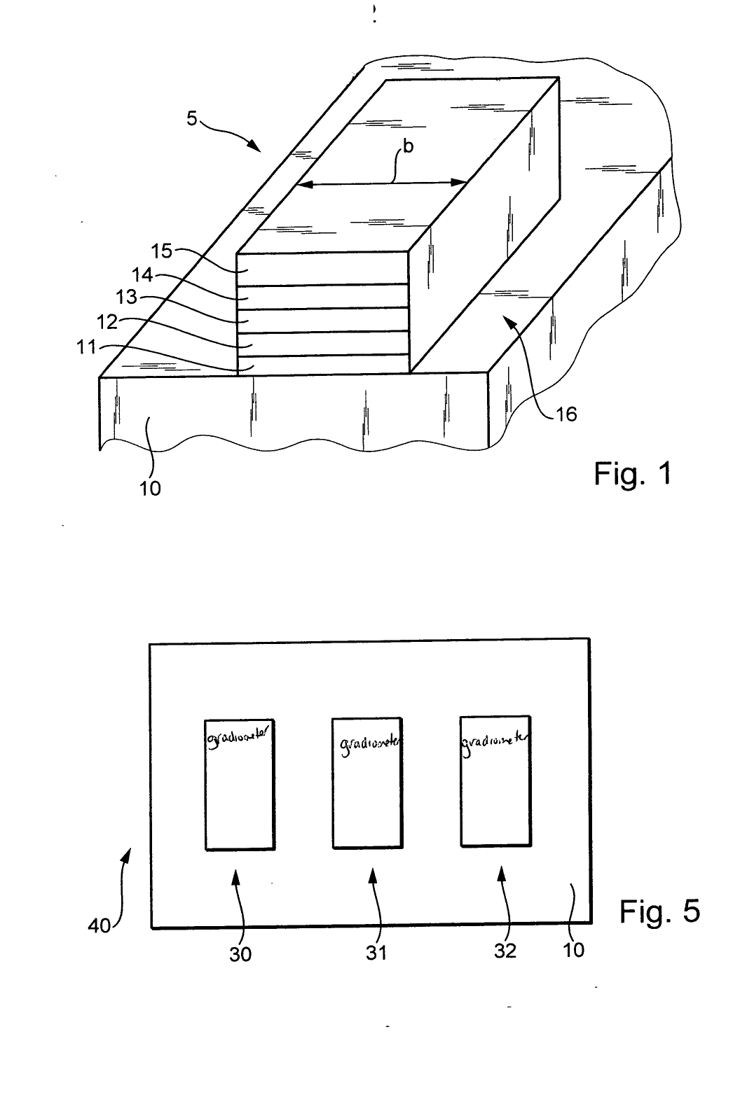

The present invention proceeds initially from a magnetoresistive layered assemblage 5, depicted in FIG. 1, based on the GMR effect and operating on the spin-valve principle.

Specifically, FIG. 1 shows that a substrate 10 is provided on which an adaptation layer 11 (“buffer layer”), made, for example, of iron or nickel-iron, is present locally. Positioned on adaptation layer 11 is a reference layer 12 whose magnetization direction is at least largely independent of the direction of an external magnetic field. Reference layer 12 is preferably made up of two sublayers, for example, an antiferromagnetic layer of nickel oxide having a thickness of, for example, 50 nm, and a soft magnetic layer of nickel-iron having a thickness of, for example, 5 nm. Additionally located on reference layer 12 is a nonmagnetic, electrically conductive intermediate layer 13, for example, made of copper. Positioned on intermediate layer 13 is a soft magnetic detection layer 14 whose magnetization direction is oriented at least approximately parallel to the direction of an external magnetic field, so that by way of the GMR effect, a change in the electrical resistance in intermediate layer 13 occurs as a function of the angle between the magnetization direction in reference layer 12 and the magnetization direction in detection layer 14. Detection layer 14 is, for example, a soft magnetic nickel-iron layer having a thickness of 5 nm. Lastly, a cover layer 15 made e.g. of tantalum is located on detection layer 14.

As shown in FIG. 1, magnetoresistive layered assemblage 5 on substrate 10 is patterned in strip form, strip 16 (visible in plan view) having a width b that is between 0.5 μm and 200 μm, in particular between 1 μm and 100 μm.

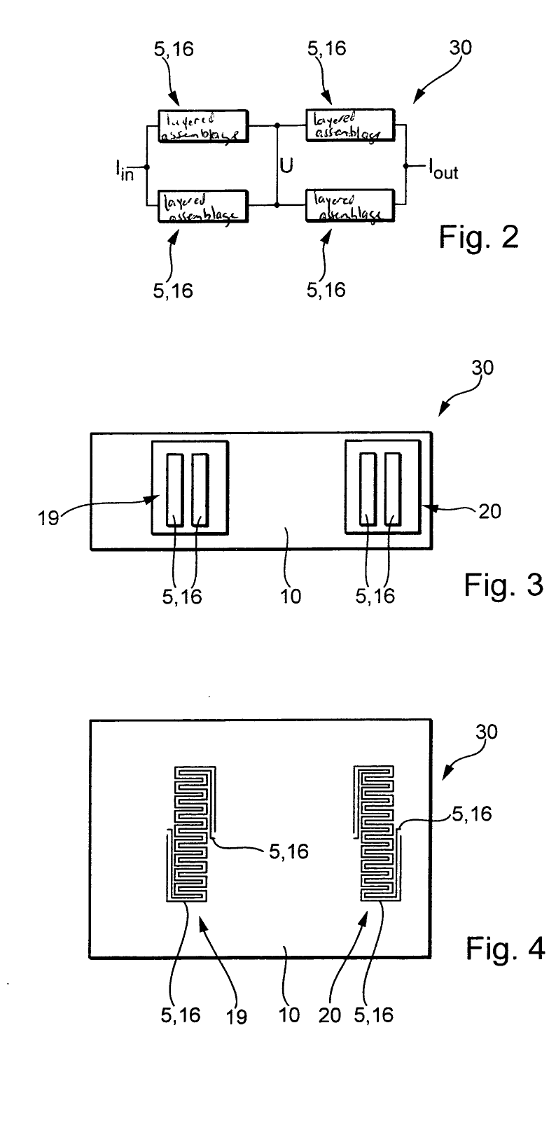

FIG. 2 shows the manner in which four magnetoresistive layered assemblages 5 according to FIG. 1, which are located on common substrate 10, are interconnected to form a Wheatstone bridge, thus producing a first gradiometer 30. In particular, provision is made in the case of FIG. 2 for magnetoresistive layered assemblages 5 each to be patterned in the form of strips 16 of identical width that each have a strip width b, this being also understood as magnetoresistive layered assemblages 5 patterned in meander form.

FIG. 3 shows, as a continuation of the schematic sketch according to FIG. 2, the manner in which the Wheatstone bridge circuit on substrate 10 is subdivided into a first half-bridge 19 and a second half-bridge 20 that are positioned physically next to one another, first half-bridge 19 and second half-bridge 20 according to FIG. 2 being interconnected to form a full bridge. In addition, both first half-bridge 19 and second half-bridge 20 each have two magnetoresistive layered assemblages 5 according to FIG. 1, each patterned in the form of strips 16 having a strip width b.

FIG. 4 more precisely depicts first half-bridge 19 and second half-bridge 20 according to FIG. 3, so that it is apparent that magnetoresistive layered assemblages 5 according to FIG. 3 are each embodied in the form of meander-shaped, closely adjacent magnetoresistive layered assemblages 5.

Further details of the configuration of magnetoresistive layered assemblage 5 and its interconnection to yield a Wheatstone bridge and a gradiometer 30 are explained in German Patent Application No. 101 28 135.8, so there is no need for further discussion of those details here.

FIG. 5 shows a sensor element in the form of a gradiometer assemblage 40 having a total of three gradiometers or full gradiometer bridges—a first gradiometer 30, a second gradiometer 31, and a third gradiometer 32—that are interconnected on common substrate 10 to yield gradiometer assemblage 40. An electrical evaluation unit (not depicted) is preferably also provided on substrate 10.

The individual gradiometers 30, 31, 32 are identical in principle, and are each configured in accordance with FIG. 2, FIG. 3, or FIG. 4. They differ only in that the strip-shaped (in plan view) magnetoresistive layered assemblages 5 constituting each of them have identical strip widths within each gradiometer 30, 31, 32, but have strip widths differing in each case from one gradiometer to another.

For example, strip width b according to FIG. 1 in gradiometer 30, i.e. in each of magnetoresistive layered assemblages 5 according to FIG. 1 constituting that gradiometer, is e.g. 0.5 μm to 2 μm, in second gradiometer 31 is correspondingly e.g. 3 μm to 7 μm, and in third gradiometer 32 is correspondingly e.g. 8 μm to 15 μm.

The strip widths are selected so that the individual measurement ranges of the individual gradiometers 30, 31, 32 combine to yield a greater overall measurement range for gradiometer assemblage 40.

Assemblage 40 is based, in particular, on the recognition that with narrow strip widths of, e.g., 1.5 μm, the change in electrical resistance as a function of a changing magnetic field has less of a slope than with a greater strip width of, for example 10 μm.

In addition, the change in resistance as a function of the magnetic field change increases (within certain limits) with strip width, so that it is advantageous to position on common substrate 10 several gradiometers 30, 31, 32 that have quite dissimilar strip widths, and that therefore cover different measurement ranges.

For optimum adaptation of gradiometer assemblage 40 to the desired measurement range for a magnetic field gradient, it is thus sufficient to record the resistance change as a function of magnetic field change for various magnetoresistive layered assemblages 5 according to FIG. 5, and then to assemble from those measurement curves the combination of gradiometers 30, 31, 32, having respectively associated strip widths, that is optimal for the individual case, i.e., the desired measurement range for a magnetic field gradient.

Depending on the individual case, it may be sufficient to position only two gradiometers on substrate 10, but it may also be necessary, in contrast to what is shown in FIG. 5, to provide a number of gradiometers 30, 31, 32 that exceeds three.

All in all, it is an insight of the present invention that the characteristic curve slope in magnetoresistive layered systems, based on the GMR effect and operating in particular according to the spin-valve principle, can be modified, and can be adjusted in controlled fashion, as a function of the feature width of the strip-shaped features.

1. A sensor element for measuring magnetic field gradients, comprising:
a substrate; and
a plurality of magnetoresistive layered assemblages positioned on the substrate, the layered assemblages each being embodied, in plan view, at least locally as strips, a first one of the layered assemblages including at least locally a first strip having a first strip width, and a second one of the layered assemblages having at least locally a second strip having a second strip width different from the first strip width.

2. The sensor element as recited in claim 1, wherein the strips have a width in a range from 0.5 μm to 200 μm.

3. The sensor element as recited in claim 1, wherein the strips have a width in a range from 1μ to 100 μm.

4. The sensor element as recited in claim 1, wherein the magnetoresistive layered assemblages operate based on one of a GMR effect or an AMR effect utilizing coupled multiple layers, or in accordance with a spin-valve principle.

5. The sensor element as recited in claim 1, wherein the layered assemblages are embodied, in plan view, at least largely in strip form.

6. The sensor element as recited in claim 6, wherein the layered assemblages are embodied, at least largely, in a form of strip meanders.

7. A gradiometer assemblage comprising:
a first gradiometer bridge including four first magnetoresistive layered assemblages interconnected in a manner of a Wheatstone bridge which are each embodied, in plan view, at least locally as strips having a first strip width;
a second gradiometer bridge including four second magnetoresistive layered assemblages interconnected in the manner of a Wheatstone bridge which are each embodied, in plan view, as strips having a second strip width different from the first strip width; and
a third gradiometer bridge including four magnetoresistive layered assemblages interconnected in the manner of a Wheatstone bridge which are each embodied, in plan view, at least locally as strips having a third strip width different from the first and the second strip width;
wherein the first gradiometer bridge, the second gradiometer bridge, and the third gradiometer bridge are positioned on a common substrate.

8. A gradiometer assemblage, comprising:
a first gradiometer bridge including four first magnetoresistive layered assemblages interconnected in the manner of a Wheatstone bridge which are each embodied, in plan view, at least locally as strips having a first strip width; and
a second gradiometer bridge including four second magnetoresistive layered assemblages interconnected in the manner of a Wheatstone bridge which are each embodied, in plan view, as strips having a second strip width different from the first strip width;
wherein the first gradiometer bridge and the second gradiometer bridge are positioned on a common substrate.

9. The gradiometer assemblage as recited in claim 8, wherein the strips have a strip width in the range from 0.5 μm to 200 μm.

10. The gradiometer assemblage according to claim 8, wherein the strips have a strip width in the range of 1 μm to 100 μm.

11. The gradiometer assemblage as recited in claim 8, wherein the first strip width is between 0.5 μm and 2 μm or between 8 μm and 15 μm; and the second strip width is between 3 μm and 7 μm.

12. The gradiometer assemblage as recited in claim 7, wherein the first strip width is between 0.5 μm and 2 μm, the second strip width is between 8 μm and 15 μm, and the third strip width is between 3 μm and 7 μm.

13. The gradiometer assemblage as recited in claim 6, further comprising:
a common electrical evaluation unit which is interconnected with the magnetoresistive layered assemblages and is also positioned on the common substrate.

14. The gradiometer assemblage as recited in claim 8, wherein the magnetoresistive layered assemblages each operate on the basis of one of a GMR effect, or an AMR effect utilizing coupled multiple layers, or in accordance with a spin-valve principle.

15. The gradiometer assemblage as recited in claim 8, wherein the layered assemblages are each embodied, in plan view, at least largely in strip form.

16. The gradiometer assemblage according to claim 15, wherein the layered assemblages are each embodied, in plan view, at least largely in a form of strip meanders.

17. A method for measuring magnetic field gradients using a gradiometer assemblage, comprising:
at least locally embodying each of a plurality of magnetoresistive layered assemblages as strips on a common substrate, each of at least two of the strips of two dissimilar layered assemblages having a different width; and
setting the widths of the strips so that in terms of a measurement range of the gradiometer assemblage for magnetic field gradients, an overall measurement range of the multiple layered assemblages exceeds individual measurement range of one individual layered assemblage.

18. The method as recited in claim 17, further comprising:
providing at least three layered assemblages having three dissimilar widths to enlarge the overall measurement range; and
setting the individual measurement ranges by way of an adaptation of the widths of the strips so as to yield a desired overall measurement range.

19. The method as recited in claim 17, further comprising:
using the gradiometer assemblage to measure magnetic field gradients over at least five orders of magnitude at magnetic field strengths from 1 μT to 30 mT.

20. The method of claim 17, further comprising:
using the gradiometer assemblage to measure field gradients over at least five orders of magnitude at magnetic field strengths from 1 μT to 10 mT.
